(19) United States
(12) Patent Application Publication
(10) Pub. No.: US 2026/0309824 A1
(43) Pub. Date: Oct. 8, 2026

(54) SIMULATION-BASED EDDY CURRENT CORRECTION FOR DIFFUSION WEIGHTED IMAGING

(71) Applicant: Siemens Healthineers AG, Forchheim (DE)

(72) Inventors: Yahang Li, Plainsboro, NJ (US); Boris Mailhe, Plainsboro, NJ (US); Mahmoud Mostapha, Princeton, NJ (US); Nirmal Janardhanan, Alpharetta, GA (US); Thorsten Feiweier, Poxdorf (DE); Stephan Kannengießer, Wuppertal (DE); Rainer Schneider, Höchstadt (DE); David Grodzki, Erlangen (DE); Daniel Niederlöhner, Erlangen (DE); Wei Liu, Erlangen (DE); Dieter Ritter, Fürth (DE); Michael Köhler, Nürnberg (DE); Mariappan S. Nadar, Plainsboro, NJ (US)

(21) Appl. No.: 19/090,949

(22) Filed: Mar. 26, 2025

(51) Int. Cl. G01R 33/565; G01R 33/563; G01R 33/58

(52) U.S. Cl. CPC G01R 33/56518; G01R 33/56341; G01R 33/58

(57) ABSTRACT

Systems and methods for simulation-based eddy current correction. A magnetic resonance (MR) simulator is used that simulates the underlying eddy current behavior for a given sequence with eddy current response functions derived from a system-wise calibration scan. A regularized least-squares reconstruction formulation is used in which the simulated eddy currents are synergistically integrated into the encoding operator.

### FIELD

This disclosure relates to medical imaging.

### BACKGROUND

Magnetic resonance imaging, or MRI, is a noninvasive medical imaging modality that can generate detailed images of almost every internal structure in the human body, including, for example organs, bones, muscles, and blood vessels. Diffusion-weighted imaging (DWI) is the use of specific MRI sequences as well as software that generates images from the resulting data that uses the diffusion of water molecules to generate contrast in an MR image.

DWI is a powerful imaging tool that can deliver both qualitative and quantitative evaluation of the molecular function and micro-structure of the human body and has been demonstrated to be very powerful on various disease treatment and progression assessments. Recent advancements in high-performance gradients have significantly enhanced the capability of DWI, e.g., shortened diffusion-encoding period and increased SNR offered by the higher gradient amplitude. However, these hardware improvements also introduce new challenges, including more pronounced eddy currents, concomitant field effects, and peripheral nerve stimulation.

In particular, strong diffusion-gradient-induced eddy currents produce spatiotemporal variations in the magnetic field, leading to severe artifacts in the final image such as geometric distortions, blurring, and/or ghosting. However, current correction solutions that perform very well on conventional gradient strengths either failed to provide satisfactory results with strong diffusion-sensitizing gradients due to the very complex nonlinear spatiotemporal magnetic field evolution induced by eddy currents (especially for diffusion-weighted multi-shot EPI experiments) or require additional sophisticated hardware for accurate dynamic field evolution measurement.

### SUMMARY

By way of introduction, the preferred embodiments described below include methods, systems, instructions, and/or computer readable media for simulation-based eddy current correction.

In a first aspect, a method for simulation-based eddy current correction, the method comprising: determining spatiotemporal eddy current characteristics of an MR scanner; performing a patient scan using a MR protocol, the patient scan generating MR data; estimating, by a MR simulator, a dynamic field based on the spatiotemporal eddy current characteristics and the MR protocol; reconstructing an image from the MR data using at least the estimated dynamic field; and outputting the image.

In a second aspect, a system for simulation-based eddy current correction, the system comprising: an magnetic resonance (MR) scanner configured to acquire MR data of a patient with a patient scan using a MR protocol, the MR scanner further configured to perform a calibration scan to determine spatiotemporal eddy current characteristics of the MR scanner; a MR simulator configured to estimate a dynamic field based on the spatiotemporal eddy current characteristics and the MR protocol; and an evaluation unit configured to reconstruct an MR image from the MR data using at least the dynamic field.

In a third aspect, a non-transitory computer implemented storage medium, including machine-readable instructions stored therein for simulation-based eddy current correction, the instructions when executed by at least one processor, cause the processor to: determine spatiotemporal eddy current characteristics of an MR scanner; acquire MR data generated by a MR scan of a patient using a MR protocol; estimate, using a MR simulator, a dynamic field based on the spatiotemporal eddy current characteristics and the MR protocol; reconstruct an image from the MR data using at least the estimated dynamic field; and output the image.

Any one or more of the aspects described above may be used alone or in combination. These and other aspects, features and advantages will become apparent from the following detailed description of preferred embodiments, which is to be read in connection with the accompanying drawings. The present invention is defined by the following claims, and nothing in this section should be taken as a limitation on those claims. Further aspects and advantages of the invention are discussed below in conjunction with the preferred embodiments and may be later claimed independently or in combination.

### BRIEF DESCRIPTION OF THE DRAWINGS

The components and the figures are not necessarily to scale, emphasis instead being placed upon illustrating the principles of the embodiments. Moreover, in the figures, like reference numerals designate corresponding parts throughout the different views.

FIG. 1 depicts an example system for magnetic resonance imaging.

FIG. 2 depicts an example workflow for simulation-based eddy current correction according to an embodiment.

FIG. 3 depicts an example method for simulation-based eddy current correction according to an embodiment.

FIG. 4 depicts an example of uncorrected and corrected images according to an embodiment.

FIG. 5 depicts an example evaluation unit for simulation-based eddy current correction according to an embodiment.

FIG. 6 depicts an example artificial neural network.

FIG. 7 depicts an example convolutional neural network.

### DETAILED DESCRIPTION

Embodiments described herein provide systems and methods for a simulation-based eddy current correction framework with a robust eddy current simulation pipeline. A simulator is used that simulates the underlying eddy current behavior for a given sequence with eddy current response functions derived from a system-wise calibration scan. A regularized least-squares reconstruction formulation is used in which the simulated eddy currents are synergistically integrated into the encoding operator, enabling effective resolution through powerful linear or nonlinear solvers depending on the regularization used).

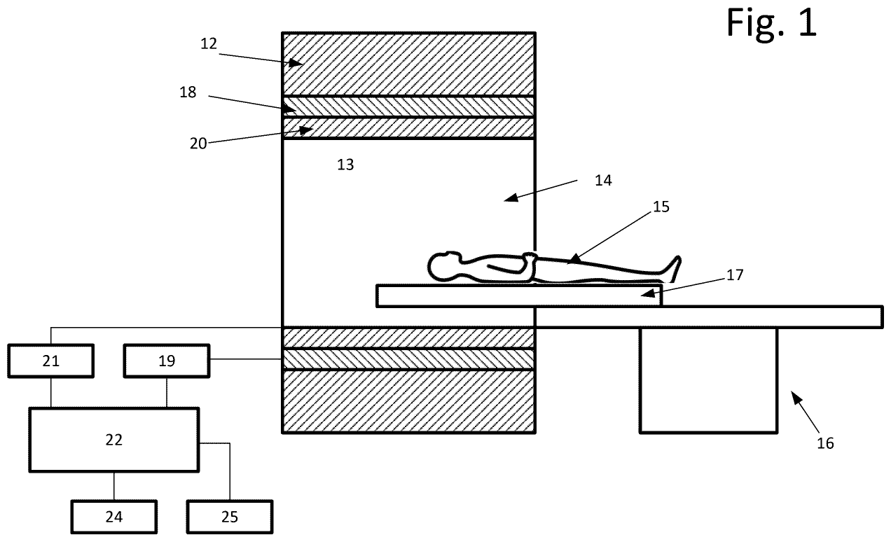

FIG. 1 depicts an example magnetic resonance apparatus 10. The magnetic resonance apparatus 10 includes a magnetic unit 11 that includes a main magnet 12 for the generation of a main magnetic field 13. In addition, the magnetic resonance apparatus 10 includes a patient receiving area 14 for receiving a patient 15. The patient receiving area 14 may be cylindrical in design and cylindrically surrounded by the magnetic unit 11 in a circumferential direction. Different designs of the patient receiving area 14 may be used. The patient 15 may be pushed into the patient receiving area 14 by a patient positioning device 16 of the magnetic resonance apparatus 10. The patient positioning device 16 includes a patient table 17 for this purpose that is configured to be movable within the patient receiving area 14.

The magnetic unit 11 also includes a gradient coil unit 18 for the generation of gradient pulses that are used for location coding during imaging. The gradient coil unit 18 is controlled by a gradient control unit 19 of the magnetic resonance apparatus 10. The magnetic unit 11 also includes a radio frequency antenna unit 20, that may be configured as a body coil permanently integrated into the magnetic resonance apparatus 10. The radio frequency antenna unit 20 is controlled by a radio frequency antenna control unit 21 of the magnetic resonance apparatus 10 and emits RF transmission pulses into an examination area during a magnetic resonance measurement, that is essentially formed by a patient receiving area 14 of the magnetic resonance apparatus 10. As a result, atomic nuclei which are present in the main magnet field 13 generated by the main magnet 12 are excited. Magnetic resonance signals are generated by relaxation of the excited atomic nuclei. The radio frequency antenna unit 20 is configured to receive magnetic resonance signals.

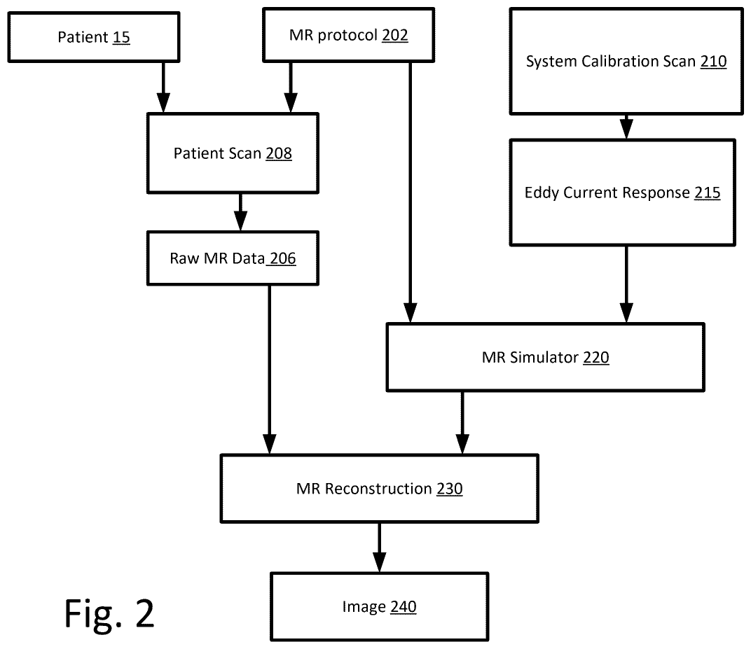

The magnetic resonance apparatus 10 has a system control unit 22 for controlling the main magnet 12, the gradient control unit 19 and for controlling the radio frequency antenna control unit 21. The system control unit 22 centrally controls the magnetic resonance apparatus 10, such as, for example, performing a predetermined imaging magnetic resonance measurement. The system control unit 22 is configured to execute a computer-implemented method for generating magnetic resonance images, as shown in FIG. 2.

In addition, the system control unit 22 includes an evaluation unit 60 not shown here in more detail for evaluating/reconstructing the magnetic resonance signals that are recorded during the magnetic resonance examination. MRI reconstruction converts the raw MRI data (measurements) from an MRI scan into interpretable medical images. The MRI scanners acquires spatial frequency data (k-space) through the application of magnetic gradients and radiofrequency pulses. Reconstruction transforms the frequency-domain data into spatial-domain images, typically via inverse Fourier transforms. Reconstruction methods may use various methods such as iterative algorithms, incorporating advanced signal processing, compressed sensing, machine learning, and differentiable physics models to correct artifacts, reduce noise, and enhance resolution. The magnetic resonance apparatus 10 further includes a user interface 23 that is connected to the system control unit 22. Control information such as, for example imaging parameters, as well as reconstructed magnetic resonance images may be displayed on a display unit 24, for example on at least one monitor, which is part of the user interface 23 for a medical operator. Furthermore, the user interface 23 has an input unit 25 by which information and/or parameters may be entered by the medical operator during a measurement process. Different imaging techniques may be used by the MRI system.

One widely used MRI technique is referred to as diffusion-weighted imaging (DWI). DWI is an imaging technique that detects the motion of water molecules within tissues, providing insights into tissue architecture and cellular integrity. Unlike conventional MRI sequences, DWI employs strong, specialized gradient pulses to encode water diffusion within the MR signal. These diffusion-sensitizing gradients attenuate the MR signal based on the mobility of water molecules; restricted diffusion yields higher signal intensity, while unrestricted diffusion produces lower signal intensity. One drawback to these strong gradients is increased eddy currents effects. Eddy currents in diffusion-weighted imaging (DWI) are unwanted transient electrical currents induced in conductive components of an MRI scanner when strong diffusion-sensitizing gradients are rapidly switched.

In general, eddy currents refer to circulating electrical currents induced in conductive materials when they are exposed to rapidly changing magnetic fields. In MRI and in particular DWI, the MRI system uses strong, rapidly switching gradients. During these rapid gradient field transitions, the intense and swiftly varying magnetic flux interacts with conductive components within the MRI scanner, such as metal housing, shields, gradient coils, or other conductive support structures, resulting in the induction of eddy currents. These induced eddy currents produce secondary magnetic fields opposing the original gradient fields, causing magnetic field distortions, interfering with the intended magnetic fields, and potentially degrading image quality. These distortions manifest as geometric inaccuracies, blurring, ghosting, spatial misregistration, and reductions in image resolution and diagnostic accuracy. Particularly in diffusion-weighted images that were acquired with the use of the echoplanar technique (EPI), eddy current-dependent distortions represent a particularly significant challenge, since a particularly high sensitivity (approximately 10 Hz per pixel in the phase coding direction) to static and dynamic field interference typically exists in EPI imaging, and high gradient amplitudes are specifically used to adjust the diffusion gradients, accompanied by correspondingly strong field perturbations.

Various methods have been used to correct for eddy currents including both hardware and software solutions. Several post-processing methods, such as FSL eddy and Dynamic Field Correction (DFC), have been proposed to address geometric distortion and blurring caused by eddy currents through image-domain registration. These methods typically assume a single deformation field, often derived from a low-b-value “reference” scan, to correct for all geometric distortions, without taking the non-constant temporal variation of the magnetic field during the image readout into consideration. Additionally, the registration-based method can have suboptimal performance when under the effect of residual ghosting or insufficient SNR, and it may introduce additional blurring during interpolation/resampling.

Ghosting artifacts primarily arise from phase inconsistencies between interleaved echoes, which can be further exacerbated by the high diffusion gradient strengths (particularly in segmented acquisitions). Data-driven methods have been proposed to actively measure and correct for the phase inconsistency between the interleaved echoes, either with or without navigator data. While these approaches work well with conventional gradient strengths, they typically underperform when strong gradients are applied due to the highly complex nonlinear spatiotemporal magnetic field variations induced by eddy currents. Model-based methods have also been proposed to handle the nonlinear phase variations between the interleaved echoes (and shots) within a reconstruction framework for high gradient strength DWI. However, these models do not explicitly account for the inherent spatiotemporal field evolution caused by eddy currents, which may lead to suboptimal performance in cases of highly undersampled acquisitions and/or large shot counts.

Recently, field-monitoring-based approaches have been proposed to directly measure and incorporate the nonlinear spatiotemporal evolution of eddy-current-induced field perturbations within a reconstruction framework. However, these methods require dedicated field probe hardware.

Embodiments described herein provide a simulation-based eddy current correction system. A MR simulator is provided that is simulating the underlying eddy current behavior for a given sequence (with eddy current response function derived from system-wise calibration scans). The system corrects for the eddy current behavior using a regularized least-squares reconstruction in which the simulated eddy currents are synergistically integrated into the encoding operator, providing effective resolution through powerful linear or nonlinear solvers (dependent on the regularizer used).

Embodiments provide a more comprehensive model to simulate the highly nonlinear spatiotemporal evolution of magnetic field changes induced by eddy currents. This approach inherently reduces model mismatch effects during correction. Additionally, the simulation-based eddy current map generation pipeline makes the method more robust when dealing with different acquisition settings. While the method uses a system calibration scan, the calibration scan is independent for different sequences and ideally is only needed once for every scanner although to capture changes over time an update of the calibration may be performed at regular intervals during regular servicing. The method also does not require additional hardware.

FIG. 2 depicts an example workflow for an eddy current correction. The raw data 206 and eddy current response 215 are measured during an imaging scan of a patient 15 using a MR protocol 202 and a calibration scan 210 respectively. The calibration scan 210 is a system-dependent scan that determines the eddy current response 215 of the specific scanner and can be performed separately at any point prior (or after) to the imaging scan. The eddy current response 215 is thus independent from the raw data 206 measurement. During preprocessing, a dynamic field is generated by a MR simulator 220 from the MR protocol 202 and the eddy current response 215. The dynamic field is input into the MR reconstruction process 230 which reconstructs an image 240 using a regularized least-square reconstruction technique with the dynamic field embedded in the imaging model.

In MRI, image reconstruction transforms the acquired frequency-domain data from an imaging scan into spatial-domain images, for example via inverse Fourier transforms. A general MR imaging equation may be written as follows:

$${d}_{c} ( t ) = {\int }_{r} {s}_{c} ( r ) ρ ( r ) {e}^{i ϕ ( r , t )} d r + {n}_{c} ( t ) ,$$

where d_{c}(t) is the k-space measurement for the c-th coil. s_{c}(r) represents the coil sensitivity for the c-th coil, ρ(r) the true image of interest, and n_{c}(t) the measurement noise. φ(r,t) denotes the phase evolution of the transverse magnetization, which, under ideal conditions, can be considered linear in space. As a result, the true image ρ(r) can be directly retrieved through a Fourier transform. However, in practice, nonlinear field perturbations (e.g., due to tissue/air susceptibility differences, static B0 inhomogeneities, gradient nonlinearities, concomitant fields or eddy current effects) disrupt the linear phase assumption. Therefore, artifacts such as geometric distortions and/or ghosting can occur when direct Fourier reconstruction is applied. To accommodate the nonlinear variation, the phase evolution φ(r,t) can be further modeled as:

$$ϕ ( r , t ) = γ {B}_{0} ( r ) t + {\sum }_{l = 1}^{L} {c}_{l} ( t ) {h}_{l} ( r ) ,$$

where B₀(r) is the susceptibility-induced and/or hardware related B₀ field inhomogeneity and γ the gyromagnetic ratio. The second term is a commonly used spherical harmonics model to represent the eddy current effect with hₗ(r) representing the solid harmonics up to the L-th order and cₗ(t) the corresponding time expansion coefficients. For the purpose of this application, the processing is focused solely on eddy current effects, and thus B₀(r) is omitted from the final imaging model (i.e., γB₀(r)t=0). During an imaging procedure, B₀(r) may be determined by alternative known means and used in the reconstruction. In an embodiment, for the eddy current component, third order spherical harmonics are used, and the expansion coefficient is determined through the MR simulator 220 with the MR protocol as well as the eddy current response function 215 derived from the calibration scan 210 as inputs.

In an embodiment, the following eddy current model is used:

$${B}_{eddy} ( t ) = - \frac{d {G}_{x} ( t )}{d t} * {f}_{x} ( t ) - \frac{d {G}_{y} ( t )}{d t} * {f}_{y} ( t ) - \frac{d {G}_{z} ( t )}{d t} * {f}_{z} ( t ) ,$$

where Gₓ(t), G_{y}(t), and G_{z}(t) are the corresponding gradient waveforms generated from a MR simulator 220 with a given sequence protocol 202. ƒₓ(t), ƒ_{y}(t), and ƒ_{z}(t) are the system-specific eddy current response 215 functions (with a mono-exponential model) and * represents a convolution operation. The l-th order expansion coefficients can then be calculated from the l-th order off-resonance B_{eddy,l} by:

$${c}_{l} ( t ) = γ {\sum }_{T = {t}_{0}}^{t} {B}_{eddy , l} ( T ) .$$

Then, with the pre-determined φ(r,t) and proper discretization, a regularized least-square reconstruction formulation is proposed to obtain the final image:

$$\hat{x} = {min}_{x} {\sum }_{c} {‖ {d}_{c} - E {S}_{c} x ‖}_{2}^{2} + λ R ( x ) ,$$

where x∈ [symbol] , d∈ [symbol] , and E∈ [symbol] is the encoding matrix with E_{n,m}=e^{iφ(r}^{ₘ}^{,t}^{ₙ}⁾. S∈ [symbol] is a diagonal matrix for the coil sensitivity maps. R(.) is the regularizer with λ being its regularization parameter. In an embodiment, a Tikhonov regularizer is used (i.e., R(x)=∥x∥₂²).

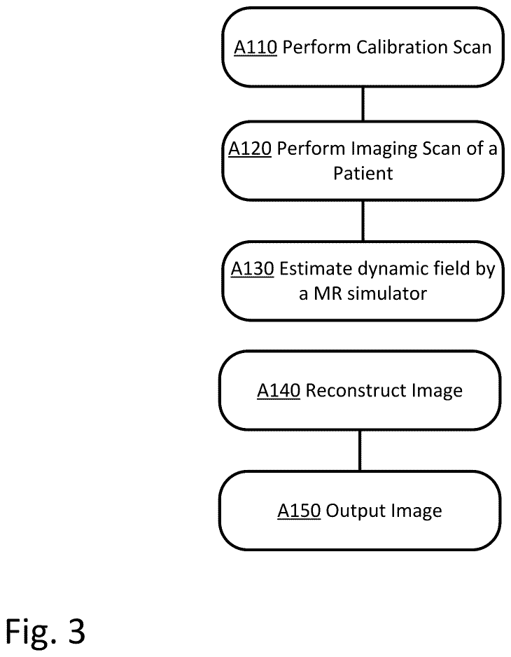

FIG. 3 depicts an example method for simulation-based eddy current correction. A calibration procedure 210 is used to obtain the spatiotemporal eddy current characteristics of an MR scanner. This information is combined with the imaging gradient waveforms to obtain the actual spatiotemporal eddy current fields which are present during the scan. The actual spatiotemporal eddy current fields are used during image reconstruction to obtain images with reduced artifacts (e.g., distortions, blurring, and/or ghosting). The method is performed by the system of FIG. 1 or another system. The method is performed in the order shown or other orders. Additional, different, or fewer acts may be provided.

At act A110, the spatiotemporal eddy current characteristics of an MR scanner are acquired by performing a calibration procedure 210. The calibration procedure 210 may be performed at any time prior to or after the subsequent imaging procedure. For example, the calibration procedure 210 may be performed annually during routine maintenance. Alternatively, the calibration procedure 210 may be performed more often, for example prior to each imaging procedure. Different scanners may have different maintenance requirements and thus have different schedules.

A calibration procedure 210 that is used to characterize the spatiotemporal eddy current behavior of an MRI scanner involves systematically measuring induced magnetic field perturbations using calibration experiments. Initially, a phantom, for example a uniform water-filled spherical or cylindrical phantom, is placed centrally within the scanner bore. The phantom should provide a homogeneous signal distribution, ensuring stable and reliable field measurements. The calibration process involves executing specialized gradient waveforms designed to induce robust and measurable eddy currents, for example involving rapid gradient switching in each principal gradient axis independently (X, Y, and Z).

For each gradient axis, a sequence of rapidly switched gradient pulses is applied, and the induced field distortions are measured over time through phase-sensitive MRI acquisitions or magnitude based methods. Specifically, a series of gradient-echo images with systematically varied echo times are collected immediately following each gradient pulse. The rapidly switching gradient fields induce eddy currents within conductive scanner components, generating secondary magnetic fields that alter the measured MRI signal phase. The phase evolution across these calibration images are analyzed allowing the system to quantify the magnitude, temporal decay constants, and spatial patterns of the eddy-current-induced magnetic fields. Analysis is performed to extract phase shifts directly attributable to eddy currents. The analysis may include fitting the acquired data to exponential decay models, revealing the characteristic amplitude, time constants, and spatial distribution of the induced fields. These calibrated parameters represent the eddy current behavior of the scanner.

At act A120, a patient scan 208 is performed using a MR protocol 202 in order to acquire MR data 206. As depicted and described in FIG. 1 above, the MR data 206 may be acquired using a MR scanner. For example, gradient coils, a whole-body coil, and/or local coils generate a pulse or scan sequence in a magnetic field created by a main magnet or coil. The whole-body coil or local coils receive MR signals. In an embodiment and used as an example below, the MR data 206 may represent image data for a brain of a patient 15. Different objects, organs, or regions of a patient 15 may also be scanned. The MR data 206 is k-space data.

Different MR protocols may be used to acquire the MR data 206. MR protocols include a variety of pulse sequences tailored to specific diagnostic purposes. Common examples include T1-weighted imaging (for anatomical detail and tissue contrast), T2-weighted imaging (highlighting fluid or edema), fluid-attenuated inversion recovery (FLAIR, sensitive to pathology), diffusion-weighted imaging (DWI) for assessing water mobility in tissues, diffusion tensor imaging (DTI, assessing white matter integrity), functional MRI (fMRI, detecting brain activation patterns), and susceptibility-weighted imaging (SWI, visualizing blood and iron content). Additional protocols include MR angiography (MRA, imaging blood vessels), spectroscopy (MRS, analyzing tissue metabolites), and gradient-echo sequences (GRE, rapid imaging, sensitive to susceptibility effects).

In an embodiment, the MR protocol is for DWI. In DWI, specialized gradient waveforms are applied to impart sensitivity to the microscopic diffusion of water molecules within biological tissues. These gradient waveforms play a central role in encoding diffusion information into the MRI signal, allowing differentiation of tissue structures based on their unique water diffusion characteristics. The gradient waveform used in diffusion MRI sequences may include two strong gradient pulses of equal amplitude, shape, and duration, separated by a controlled time interval. One widely adopted gradient waveform is the Stejskal-Tanner waveform, which consists of two gradient pulses, for example of opposite polarity along a selected spatial axis, separated by a diffusion time interval (often called the diffusion encoding time). When these paired gradient pulses are applied, water molecules undergoing random Brownian motion experience a phase dispersion proportional to the gradient amplitude, duration, interval between gradient pulses, and their diffusion characteristics. Consequently, stationary water molecules accumulate no net phase shift between gradient pulses, while diffusing water molecules accumulate significant phase dispersion, resulting in attenuation of measured MRI signals. The result of the patient scan 208 is MR data 206 acquired using a specific MR protocol 202. This information may be input into the MR simulator 220 as described below.

At act A130, a dynamic field is estimated based on the spatiotemporal eddy current characteristics, eddy current response 215, and the MR protocol 202. The dynamic magnetic field is generated by an MR simulator 220, incorporating both the prescribed MR protocol 202 and the scanner's eddy current response 215. The dynamic field describes a realistic time-dependent magnetic environment experienced during the MR data 206 acquisition. In an embodiment, the MR simulator 220 generates the idealized magnetic gradient waveforms prescribed by the protocol. The idealized gradient waveforms are mathematically convolved with the measured eddy current impulse response, previously characterized through the calibration procedure 210. The eddy current response 215, quantified in terms of amplitude, spatial distribution, and temporal decay characteristics, captures the scanner-specific secondary magnetic fields induced when gradient pulses rapidly switch. Convolution of these two components produces a dynamic magnetic field simulation that closely mirrors actual scanner performance during the imaging session. The estimated dynamic magnetic field thus reflects both the ideal gradients intended by the imaging sequence and the realistic distortions and transient secondary fields induced by eddy currents.

At act A140, an image 240 is reconstructed from the MR data 206 using at least the estimated dynamic magnetic field. In MR the process of image reconstruction may be formulated mathematically as a regularized least-square optimization problem. The goal is to recover an image from measured MR data 206 (k-space data). Mathematically, the regularized least-square reconstruction problem involves minimizing a cost function comprising two distinct components: a data fidelity term and a regularization term. This optimization problem (as described below) may be represented as:

$$\hat{x} = {min}_{x} {\sum }_{c} {‖ {d}_{c} - E {S}_{c} x ‖}_{2}^{2} + λ R ( x ) ,$$

where x∈ [symbol] , d∈ [symbol] , and E∈ [symbol] is the encoding matrix with E_{n,m}=e^{iφ(r}^{ₘ}^{,t}^{ₙ}⁾. S∈ [symbol] is a diagonal matrix for the coil sensitivity maps. x is the desired image. R(.) is the regularizer with λ being its regularization parameter. Potential regularizers include Tikhonov regularization, total variation (TV), or sparsity-promoting terms. In an embodiment, a Tikhonov regularizer is used

$$( i . e . , R ( x ) = {‖ x ‖}_{2}^{2} ) .$$

Alternatively, the total variation (TV) regularization enforces piecewise smoothness. The choice of λ is also important and may be determined via empirical methods such as cross-validation or analytical techniques such as L-curve analysis. The solution to the optimization problem may use iterative numerical methods such as gradient descent or conjugate gradient algorithms. Both linear and nonlinear methods may be used to solve the optimization problem depending on the choice of regularization term and problem formulation.

Linear reconstruction algorithms, such as conjugate gradient (CG) or other iterative least-squares solvers, may be applied when the regularization term is quadratic (e.g., Tikhonov regularization). The linear algorithms efficiently minimize the quadratic cost function by iteratively updating image estimates. Nonlinear reconstruction algorithms may be used when nonlinear regularizers are applied, such as total variation (TV), or sparsity constraints (compressed sensing), which are inherently nonlinear. In such cases, nonlinear optimization methods—including, proximal gradient methods (such as fast iterative shrinkage-thresholding algorithm, FISTA and iterative soft-thresholding, ISTA), alternating direction method of multipliers (ADMM), and Newton-based iterative solvers—are used. These algorithms iteratively update the reconstructed images by alternating between solving simplified subproblems and applying nonlinear thresholding or projections.

In an embodiment, R(x) may also be a learned regularizer (also a nonlinear regularizer) and can be enforced effectively through un-rolling or more advanced diffusion plug-and-play based method.

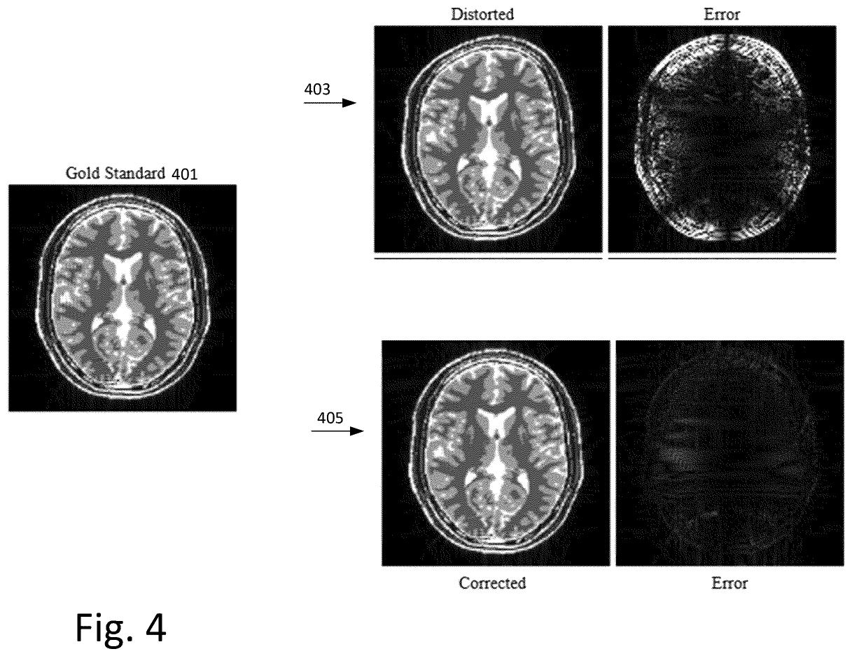

At act A150, the image 240 is output, for example displayed to an operator or user. The image 240 may be further processed using additional reconstruction algorithms or diagnosis programs. FIG. 4 depicts several examples of MR images. FIG. 4 depicts a gold standard image 401 and two sets of processed images 403 and 405. The top image has not been corrected and thus shows drastic levels of distortion. The bottom image has been corrected using the techniques described herein. The error of the corrected reconstruction image (as calculated vs the gold standard image; 20× amplified) has been diminished.

The method of FIG. 3 employs a more comprehensive model to simulate the highly nonlinear spatiotemporal evolution of magnetic field changes induced by eddy currents. This approach inherently reduces model mismatch effects during correction. Additionally, the simulation-based eddy current map generation pipeline makes the proposed method more robust when dealing with different acquisition settings. In addition, the system-wise calibration is independent for different sequences and ideally is only needed once for every scanner. The method does not require any additional hardware.

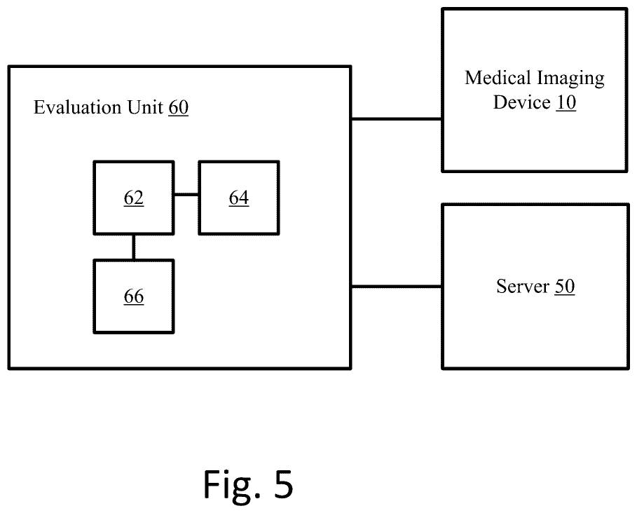

FIG. 5 depicts an example system for simulation-based eddy current correction. The system is configured to perform the method of FIG. 3 and other acts described herein. In FIG. 5, an evaluation unit 60 includes a processor 62, memory 64, and interface 66. In an embodiment, the evaluation unit 60 is configured for reconstruction an image using simulation-based eddy current correction. The evaluation unit 60 is in communication with a medical imaging device 10, for example as described in FIG. 1, and a server 50. The evaluation unit includes a processor 62, a memory 64, and an interface 66. The medical imaging device is configured to acquire MR imaging data, for example k-space data that is reconstructed into an MR image of an organ or region of a patient 15. The evaluation unit 60 is configured to reconstruct the image from the MR data 206 acquired by the medical imaging device 10. The reconstructed image may be a two-dimensional distribution of pixels representing an area of the patient 15 and/or a three-dimensional distribution of voxels representing a volume of the patient 15. The processor is configured to implement a MR simulator 220 configured to simulate the highly nonlinear spatiotemporal evolution of magnetic field changes induced by eddy currents. The memory 64 is configured to store instructions and the parameters for the model(s). The interface 66 is configured to display the reconstructed images and/or accept inputs from a user. The server 50 may perform similar tasks as the evaluation unit 60 and/or may provide additional processing, storage, or analysis for example using a cloud based platform.

In an embodiment, the medical imaging device 10 is an MR imaging device 10, for example, as described above in FIG. 1. The MR system 10 of FIG. 1 includes an MR scanner or system, a computer based on data obtained by MR scanning, a server, or another processor. The MR imaging device 10 is only exemplary, and a variety of MR scanning systems may be used to collect the MR data 206. The MR imaging device 10 (also referred to as a MR scanner or image scanner) is configured to scan a patient 15. The MR imaging device 10 scans a patient 15 to provide k-space measurements (measurements in the frequency domain) using a specific protocol. The protocol and k-space measurements are input into a MR simulator 220 that may be stored in the memory 64 and implemented by the processor 62. The medical imaging device 10 is further configured to perform a calibration scan 210 to determine an eddy current response 215 for the medical imaging device 10.

The processor 62 may include an image processor that generates a reconstructed image, for example using a machine learning network (machine learning model). The image processor is a general processor, digital signal processor, three-dimensional data processor, graphics processing unit, application specific integrated circuit, field programmable gate array, artificial intelligence processor, digital circuit, analog circuit, combinations thereof, or another now known or later developed device for image generation. The image processor is a single device, a plurality of devices, or a network. For more than one device, parallel or sequential division of processing may be used. Different devices making up the image processor may perform different functions. In one embodiment, the image processor is also a control processor or other processor of the imaging device. Other image processors of the imaging device or external to the imaging device may be used. The image processor is configured by software, firmware, and/or hardware to process the data acquired by the imaging device and output one or more images.

The interface 66 includes an input device and an output device. The input may be an interface, such as interfacing with a computer network, memory, database, medical image storage, or other source of input data. The input may be a user input device, such as a mouse, trackpad, keyboard, roller ball, touch pad, touch screen, or another apparatus for receiving user input. The output is a display device but may be an interface. The field inhomogeneity maps, and/or tissue parameter maps are displayed. In another example, a high resolution image of a region of the patient 15 is displayed. The display is a CRT, LCD, plasma, projector, printer, or other display device. The display is configured by loading an image to a display plane or buffer. The display is configured to display a reconstructed image(s) of the region of the patient 15. The interface 66 may include a graphical user interface (GUI) enabling user interaction with the medical imaging device and enables user modification or selections in substantially real time.

The instructions for implementing the processes, methods, and/or techniques discussed herein are provided on non-transitory computer-readable storage media or memories, such as a cache, buffer, RAM, removable media, hard drive, or other computer readable storage media, for example the memory 64. The instructions are executable by the processor or another processor. Computer readable storage media include various types of volatile and nonvolatile storage media. The functions, acts or tasks illustrated in the figures or described herein are executed in response to one or more sets of instructions stored in or on computer readable storage media. The functions, acts or tasks are independent of the instructions set, storage media, processor or processing strategy and may be performed by software, hardware, integrated circuits, firmware, micro code, and the like, operating alone or in combination. In one embodiment, the instructions are stored on a removable media device for reading by local or remote systems. In other embodiments, the instructions are stored in a remote location for transfer through a computer network. In yet other embodiments, the instructions are stored within a given computer, CPU, GPU, or system. Because some of the constituent system components and method steps depicted in the accompanying figures may be implemented in software, the actual connections between the system components (or the process steps) may differ depending upon the manner in which the present embodiments are programmed.

In an embodiment, the processor 62 implements one or more machine learning networks that are stored in the memory in order to provide the MR simulation. In general, a trained machine learning network mimics cognitive functions that humans associate with other human minds. In particular, by training based on training data the machine learning network is able to adapt to new circumstances and to detect and extrapolate patterns. Another term for “trained machine learning network” is “trained function”. In general, parameters of a machine learning network can be adapted by means of training. In particular, supervised training, semi-supervised training, unsupervised training, reinforcement learning and/or active learning can be used. Furthermore, representation learning (an alternative term is “feature learning”) can be used. In particular, the parameters of the machine learning networks can be adapted iteratively by several steps of training. In particular, within the training a certain cost function can be minimized. In particular, within the training of a neural network the backpropagation algorithm can be used. In particular, a machine learning network may comprise a neural network, a support vector machine, a decision tree and/or a Bayesian network, and/or the machine learning network can be based on k-means clustering, Q-learning, genetic algorithms, and/or association rules. In particular, a neural network can be a deep neural network, a convolutional neural network, or a convolutional deep neural network. Furthermore, a neural network can be an adversarial network, a deep adversarial network, a generative network, and/or a generative adversarial network. In an embodiment, the image reconstruction frameworks is provided by or implemented with a neural network trained using deep learning. The network(s) may be defined as a plurality of sequential feature units or layers. Sequential is used to indicate the general flow of output feature values from one layer to input to a next layer. The information from the next layer is fed to a next layer, and so on until the final output. The layers may only feed forward or may be bi-directional, including some feedback to a previous layer. The nodes of each layer or unit may connect with all or only a sub-set of nodes of a previous and/or subsequent layer or unit. Skip connections may be used, such as a layer outputting to the sequentially next layer as well as other layers. Rather than pre-programming the features and trying to relate the features to attributes, the deep architecture is defined to learn the features at different levels of abstraction the input data. The features are learned to reconstruct lower level features (i.e., features at a more abstract or compressed level). For example, features for generating a fused image or higher resolution image are learned. For a next unit, features for reconstructing the features of the previous unit are learned, providing more abstraction. Each node of the unit represents a feature. Different units are provided for learning different features.

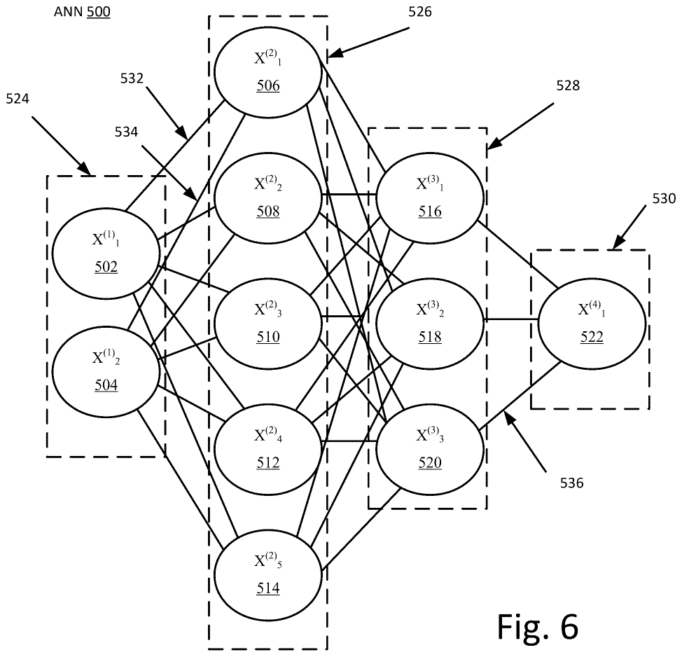

Various units or layers may be used, such as convolutional, pooling (e.g., max-pooling), deconvolutional, fully connected, or other types of layers. Within a unit or layer, any number of nodes is provided. For example, 100 nodes are provided. Later or subsequent units may have more, fewer, or the same number of nodes. In general, for convolution, subsequent units have more abstraction. FIG. 6 shows an embodiment of an artificial neural network (ANN) 500, in accordance with one or more embodiments. Alternative terms for “artificial neural network” are “neural network”, “artificial neural net” or “neural net”. The artificial neural network 500 may be used in part in, for example, the one or more machine learning based networks utilized for the diffusion network(s), etc.

The artificial neural network 500 includes nodes 502-522 and edges 532, 534, . . . , 536, wherein each edge 532, 534, . . . , 536 is a directed connection from a first node 502-522 to a second node 502-522. In general, the first node 502-522 and the second node 502-522 are different nodes 502-522, it is also possible that the first node 502-522 and the second node 502-522 are identical. For example, in FIG. 6, the edge 532 is a directed connection from the node 502 to the node 506, and the edge 534 is a directed connection from the node 504 to the node 506. An edge 532, 534, . . . , 536 from a first node 502-522 to a second node 502-522 is also denoted as “ingoing edge” for the second node 502-522 and as “outgoing edge” for the first node 502-522.

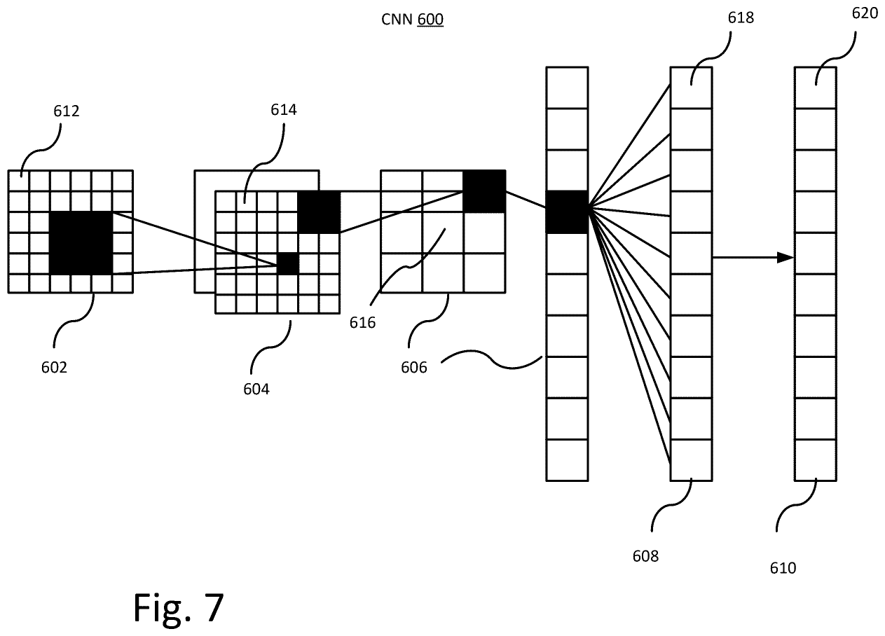

In this embodiment, the nodes 502-522 of the artificial neural network 500 may be arranged in layers 524-530, wherein the layers may include an intrinsic order introduced by the edges 532, 534, . . . , 536 between the nodes 502-522. In particular, edges 532, 534, . . . , 536 may exist only between neighboring layers of nodes. In the embodiment shown in FIG. 7, there is an input layer 524 including only nodes 502 and 504 without an incoming edge, an output layer 530 including only node 522 without outgoing edges, and hidden layers 526, 528 in-between the input layer 524 and the output layer 530. In general, the number of hidden layers 526, 528 may be chosen arbitrarily. The number of nodes 502 and 504 within the input layer 524 usually relates to the number of input values of the neural network 500, and the number of nodes 522 within the output layer 530 usually relates to the number of output values of the neural network 500.

In particular, a (real) number may be assigned as a value to every node 502-522 of the neural network 500. Here, x⁽ⁿ⁾ᵢ denotes the value of the i-th node 502-522 of the n-th layer 524-530. The values of the nodes 502-522 of the input layer 524 are equivalent to the input values of the neural network 500, the value of the node 522 of the output layer 530 is equivalent to the output value of the neural network 500. Furthermore, each edge 532, 534, . . . , 536 may include a weight being a real number, in particular, the weight is a real number within the interval [−1, 1] or within the interval [0, 1]. Here, w^{(m,n)}_{i,j} denotes the weight of the edge between the i-th node 502-522 of the m-th layer 524-530 and the j-th node 502-522 of the n-th layer 524-530. Furthermore, the abbreviation w⁽ⁿ⁾_{i,j} is defined for the weight w^{(n,n+1)}_{i,j}.

In particular, to calculate the output values of the neural network 500, the input values are propagated through the neural network. In particular, the values of the nodes 502-522 of the (n+1)-th layer 524-530 may be calculated based on the values of the nodes 502-522 of the n-th layer 524-530 by

$${x}_{j}^{( n + 1 )} = f ( {\sum }_{i} {x}_{i}^{( n )} \cdot {w}_{i , j}^{( n )} ) .$$

Herein, the function f is a transfer function (another term is “activation function”). Known transfer functions are step functions, sigmoid function (e.g. the logistic function, the generalized logistic function, the hyperbolic tangent, the Arctangent function, the error function, the smoothstep function) or rectifier functions. The transfer function is mainly used for normalization purposes.

In particular, the values are propagated layer-wise through the neural network, wherein values of the input layer 524 are given by the input of the neural network 500, wherein values of the first hidden layer 526 may be calculated based on the values of the input layer 524 of the neural network, wherein values of the second hidden layer 528 may be calculated based in the values of the first hidden layer 526, etc.

In order to set the values w^{(m,n)}_{i,j} for the edges, the neural network 500 has to be trained using training data. In particular, training data includes training input data and training output data (denoted as tᵢ). For a training step, the neural network 500 is applied to the training input data to generate calculated output data. In particular, the training data and the calculated output data include a number of values, said number being equal with the number of nodes of the output layer.

In particular, a comparison between the calculated output data and the training data is used to recursively adapt the weights within the neural network 500 (backpropagation algorithm). In particular, the weights are changed according to

$${w}_{i , j}^{′ ( n )} = {w}_{i , j}^{( n )} - γ \cdot {δ}_{j}^{( n )} \cdot {x}_{i}^{( n )}$$

wherein γ is a learning rate, and the numbers δ⁽ⁿ⁾ⱼ may be recursively calculated as

$${δ}_{j}^{( n )} = ( {\sum }_{k} {δ}_{k}^{( n + 1 )} \cdot {w}_{j , k}^{( n + 1 )} ) \cdot {f}^{′} ( {\sum }_{i} {x}_{i}^{( n )} \cdot {w}_{i , j}^{( n )} )$$

based on δ⁽ⁿ⁺¹⁾ⱼ, if the (n+1)-th layer is not the output layer, and

$${δ}_{j}^{( n )} = ( {x}_{k}^{( n + 1 )} - {t}_{j}^{( n + 1 )} ) \cdot {f}^{′} ( {\sum }_{i} {x}_{i}^{( n )} \cdot {w}_{i , j}^{( n )} )$$

if the (n+1)-th layer is the output layer 530, wherein f′ is the first derivative of the activation function, and y⁽ⁿ⁺¹⁾ⱼ is the comparison training value for the j-th node of the output layer 530.

FIG. 7 shows a convolutional neural network (CNN) 600, in accordance with one or more embodiments. Machine learning networks described herein, such as, e.g., the diffusion network(s) etc. may be implemented using convolutional neural network 600.

In the embodiment shown in FIG. 7 the convolutional neural network 600 includes an input layer 602, a convolutional layer 604, a pooling layer 606, a fully connected layer 608, and an output layer 610. Alternatively, the convolutional neural network 600 may include several convolutional layers 604, several pooling layers 606, and several fully connected layers 608, as well as other types of layers. The order of the layers may be chosen arbitrarily, usually fully connected layers 608 are used as the last layers before the output layer 610.

In particular, within a convolutional neural network 600, the nodes 612-620 of one layer 602-610 may be considered to be arranged as a d-dimensional matrix or as a d-dimensional image. In particular, in the two-dimensional case the value of the node 612-620 indexed with i and j in the n-th layer 602-610 may be denoted as x⁽ⁿ⁾_{[i,j]}. However, the arrangement of the nodes 612-620 of one layer 602-610 does not have an effect on the calculations executed within the convolutional neural network 600 as such, since these are given solely by the structure and the weights of the edges.

In particular, a convolutional layer 604 is characterized by the structure and the weights of the incoming edges forming a convolution operation based on a certain number of kernels. In particular, the structure and the weights of the incoming edges are chosen such that the values x⁽ⁿ⁾ₖ of the nodes 614 of the convolutional layer 604 are calculated as a convolution x⁽ⁿ⁾ₖ=Kₖ*x⁽ⁿ⁻¹⁾ based on the values x⁽ⁿ⁻¹⁾ of the nodes 612 of the preceding layer 602, where the convolution * is defined in the two-dimensional case as:

$${x}_{k}^{( n )} [ i , j ] = ( {K}_{k} * {x}^{( n - 1 )} ) [ i , j ] = {\sum }_{{i}^{′}} {\sum }_{{j}^{′}} {K}_{k} [ {i}^{′} , {j}^{′} ] \cdot {x}^{( n - 1 )} [ i - {i}^{′} , j - {j}^{′} ] .$$

Here the k-th kernel Kₖ is a d-dimensional matrix (in this embodiment a two-dimensional matrix), which is usually small compared to the number of nodes 612-618 (e.g. a 3×3 matrix, or a 5×5 matrix). In particular, this implies that the weights of the incoming edges are not independent, but chosen such that they produce said convolution equation. In particular, for a kernel being a 3×3 matrix, there are only 9 independent weights (each entry of the kernel matrix corresponding to one independent weight), irrespectively of the number of nodes 612-620 in the respective layer 602-610. In particular, for a convolutional layer 604, the number of nodes 614 in the convolutional layer is equivalent to the number of nodes 612 in the preceding layer 602 multiplied with the number of kernels.

If the nodes 612 of the preceding layer 602 are arranged as a d-dimensional matrix, using a plurality of kernels may be interpreted as adding a further dimension (denoted as “depth” dimension), so that the nodes 614 of the convolutional layer 604 are arranged as a (d+1)-dimensional matrix. If the nodes 612 of the preceding layer 602 are already arranged as a (d+1)-dimensional matrix including a depth dimension, using a plurality of kernels may be interpreted as expanding along the depth dimension, so that the nodes 614 of the convolutional layer 604 are arranged also as a (d+1)-dimensional matrix, wherein the size of the (d+1)-dimensional matrix with respect to the depth dimension is by a factor of the number of kernels larger than in the preceding layer 602.

The advantage of using convolutional layers 604 is that spatially local correlation of the input data may exploited by enforcing a local connectivity pattern between nodes of adjacent layers, in particular by each node being connected to only a small region of the nodes of the preceding layer.

In the embodiment shown in FIG. 7, the input layer 602 includes 36 nodes 612, arranged as a two-dimensional 6×6 matrix. The convolutional layer 604 includes 72 nodes 614, arranged as two two-dimensional 6×6 matrices, each of the two matrices being the result of a convolution of the values of the input layer with a kernel. Equivalently, the nodes 614 of the convolutional layer 604 may be interpreted as arranged as a three-dimensional 6×6×2 matrix, wherein the last dimension is the depth dimension.

A pooling layer 606 may be characterized by the structure and the weights of the incoming edges and the activation function of its nodes 616 forming a pooling operation based on a non-linear pooling function f. For example, in the two dimensional case the values x⁽ⁿ⁾ of the nodes 616 of the pooling layer 606 may be calculated based on the values x⁽ⁿ⁻¹⁾ of the nodes 614 of the preceding layer 604 as

$${x}^{( n )} [ i , j ] = f ( {x}^{( n - 1 )} [ {id}_{1} , {jd}_{2} ] , … , {x}^{( n - 1 )} [ {id}_{1} + {d}_{1} - 1 , {jd}_{2} + {d}_{2} - 1 ] )$$

In other words, by using a pooling layer 606, the number of nodes 614, 616 may be reduced, by replacing a number d1·d2 of neighboring nodes 614 in the preceding layer 604 with a single node 616 being calculated as a function of the values of said number of neighboring nodes in the pooling layer. In particular, the pooling function f may be the max-function, the average, or the L2-Norm. In particular, for a pooling layer 606 the weights of the incoming edges are fixed and are not modified by training.

The advantage of using a pooling layer 606 is that the number of nodes 614, 616 and the number of parameters is reduced. This leads to the amount of computation in the network being reduced and to a control of overfitting.

In the embodiment shown in FIG. 7, the pooling layer 606 is a max-pooling, replacing four neighboring nodes with only one node, the value being the maximum of the values of the four neighboring nodes. The max-pooling is applied to each d-dimensional matrix of the previous layer; in this embodiment, the max-pooling is applied to each of the two two-dimensional matrices, reducing the number of nodes from 72 to 9.

A fully-connected layer 608 may be characterized by the fact that a majority, in particular, all edges between nodes 616 of the previous layer 606 and the nodes 618 of the fully-connected layer 608 are present, and wherein the weight of each of the edges may be adjusted individually.

In this embodiment, the nodes 616 of the preceding layer 606 of the fully-connected layer 608 are displayed both as two-dimensional matrices, and additionally as non-related nodes (indicated as a line of nodes, wherein the number of nodes was reduced for a better presentability). In this embodiment, the number of nodes 618 in the fully connected layer 608 is equal to the number of nodes 616 in the preceding layer 606. Alternatively, the number of nodes 616, 618 may differ.

A convolutional neural network 600 may also include a ReLU (rectified linear units) layer or activation layers with non-linear transfer functions. In particular, the number of nodes and the structure of the nodes contained in a ReLU layer is equivalent to the number of nodes and the structure of the nodes contained in the preceding layer. In particular, the value of each node in the ReLU layer is calculated by applying a rectifying function to the value of the corresponding node of the preceding layer.

The input and output of different convolutional neural network blocks may be wired using summation (residual/dense neural networks), element-wise multiplication (attention) or other differentiable operators. Therefore, the convolutional neural network architecture may be nested rather than being sequential if the whole pipeline is differentiable.

In particular, convolutional neural networks 600 may be trained based on the backpropagation algorithm. For preventing overfitting, methods of regularization may be used, e.g. dropout of nodes 612-620, stochastic pooling, use of artificial data, weight decay based on the L1 or the L2 norm, or max norm constraints. Different loss functions may be combined for training the same neural network to reflect the joint training objectives. A subset of the neural network parameters may be excluded from optimization to retain the weights pretrained on another datasets.

It is to be understood that the elements and features recited in the appended claims may be combined in different ways to produce new claims that likewise fall within the scope of the present embodiments. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present embodiments have been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

The following is a list of non-limiting illustrative embodiments disclosed herein: Illustrative embodiment 1: A method for simulation-based eddy current correction, the method comprising: determining spatiotemporal eddy current characteristics of an MR scanner; performing a patient scan using a MR protocol, the patient scan generating MR data; estimating, by a MR simulator, a dynamic field based on the spatiotemporal eddy current characteristics and the MR protocol; reconstructing an image from the MR data using at least the estimated dynamic field; and outputting the image.

Illustrative embodiment 2: the method of claim 1, wherein determining the spatiotemporal eddy current characteristics of the MR scanner comprises: performing a calibration scan by the MR scanner.

Illustrative embodiment 3: the method of claim 1, wherein the patient scan is performed with diffusion weighted imaging (DWI).

Illustrative embodiment 4: the method of claim 1, wherein estimating the dynamic field comprises a realistic time-dependent magnetic environment experienced during the patient scan.

Illustrative embodiment 5: the method of claim 1, wherein reconstructing comprises reconstructing the image using a regularized least-square optimization.

Illustrative embodiment 6: the method of claim 5, wherein the regularized least-square optimization comprises solving:

$$\hat{x} = {min}_{x} {\sum }_{c} {‖ {d}_{c} - {ES}_{c} x ‖}_{2}^{2} + λ R ( x ) ,$$

where x∈ [symbol] , d∈ [symbol] , and E∈ [symbol] is the encoding matrix with E_{n,m}=e^{iφ(r}^{ₘ}^{,t}^{ₙ}⁾, S∈ [symbol] is a diagonal matrix for the coil sensitivity maps, R(.) is a regularizer with λ being a regularization parameter.

Illustrative embodiment 7: the method of claim 6, wherein:

$$ϕ ( r , t ) = γ {B}_{0} ( r ) t + {\sum }_{l = 1}^{L} {c}_{l} ( t ) {h}_{l} ( r ) ,$$

where B₀(r) is the susceptibility-induced and/or hardware related B₀ field inhomogeneity and γ the gyromagnetic ratio, wherein:

$${c}_{l} ( t ) = γ {\sum }_{T = {t}_{0}}^{t} {B}_{eddy , l} ( T ) .$$

wherein:

$${B}_{eddy} ( t ) = - \frac{{dG}_{x} ( t )}{dt} * {f}_{x} ( t ) - \frac{{dG}_{y} ( t )}{dt} * {f}_{y} ( t ) - \frac{{dG}_{z} ( t )}{dt} * {f}_{z} ( t ) ,$$

where Gₓ(t), G_{y}(t), and G_{z}(t) are corresponding gradient waveforms generated by the MR simulator with the MR protocol and ƒₓ(t), ƒ_{y}(t), and ƒ_{z}(t) are system-specific eddy current response functions provided by the spatiotemporal eddy current characteristics and * represents a convolution operation.

Illustrative embodiment 8: the method of claim 6, wherein the regularizer is a Tikhonov regularizer, wherein

$$R ( x ) = {‖ x ‖}_{2}^{2} .$$

Illustrative embodiment 9: the method of claim 6, wherein the regularizer is a learned regularizer that is enforced effectively through an unrolled iterative algorithm or a diffusion plug-and-play based method, wherein a linear reconstruction algorithm is used to solve the least-square optimization.

Illustrative embodiment 10: A system for simulation-based eddy current correction, the system comprising: an magnetic resonance (MR) scanner configured to acquire MR data of a patient with a patient scan using a MR protocol, the MR scanner further configured to perform a calibration scan to determine spatiotemporal eddy current characteristics of the MR scanner; a MR simulator configured to estimate a dynamic field based on the spatiotemporal eddy current characteristics and the MR protocol; and an evaluation unit configured to reconstruct an MR image from the MR data using at least the dynamic field.

Illustrative embodiment 11: the system of claim 10, wherein the dynamic field comprises an estimated of a realistic time-dependent magnetic environment experienced during the patient scan.

Illustrative embodiment 12: the system of claim 10, wherein the evaluation unit is configured to reconstruct the MR image using a regularized least-square optimization.

Illustrative embodiment 13: the system of claim 12, wherein the regularized least-square optimization comprises solving

$$\hat{x} = {min}_{x} {\sum }_{c} {‖ {d}_{c} - {ES}_{c} x ‖}_{2}^{2} + λ R ( x )$$

where x∈ [symbol] , d∈ [symbol] , and E∈ [symbol] is the encoding matrix with E_{n,m}=e^{iφ(r}^{ₘ}^{,t}^{ₙ}⁾, S∈ [symbol] is a diagonal matrix for the coil sensitivity maps, R(.) is a regularizer with λ being a regularization parameter.

Illustrative embodiment 14: the system of claim 13, wherein:

$$ϕ ( r , t ) = γ {B}_{0} ( r ) t + {\sum }_{l = 1}^{L} {c}_{l} ( t ) {h}_{l} ( r )$$

where B₀(r) is the susceptibility-induced and/or hardware related B₀ field inhomogeneity and γ the gyromagnetic ratio, wherein:

$${c}_{l} ( t ) = γ {\sum }_{T = {t}_{0}}^{t} {B}_{eddy , l} ( T )$$

and wherein:

$${B}_{eddy} ( t ) = - \frac{{dG}_{x} ( t )}{dt} * {f}_{x} ( t ) - \frac{{dG}_{y} ( t )}{dt} * {f}_{y} ( t ) - \frac{{dG}_{z} ( t )}{dt} * {f}_{z} ( t )$$

where Gₓ(t), G_{y}(t), and G_{z}(t) are corresponding gradient waveforms generated by the MR simulator with the MR protocol and ƒₓ(t), ƒ_{y}(t), and ƒ_{z}(t) are system-specific eddy current response functions provided by the spatiotemporal eddy current characteristics and * represents a convolution operation.

Illustrative embodiment 15: the system of claim 13 wherein the regularizer is a Tikhonov regularizer, wherein

$$R ( x ) = {‖ x ‖}_{2}^{2} .$$

Illustrative embodiment 16: the system of claim 15, wherein a linear reconstruction algorithm is used to solve the least-square optimization.

Illustrative embodiment 17: a non-transitory computer implemented storage medium, including machine-readable instructions stored therein for simulation-based eddy current correction, the instructions when executed by at least one processor, cause the processor to: determine spatiotemporal eddy current characteristics of an MR scanner; acquire MR data generated by a MR scan of a patient using a MR protocol; estimate, using a MR simulator, a dynamic field based on the spatiotemporal eddy current characteristics and the MR protocol; reconstruct an image from the MR data using at least the estimated dynamic field; and output the image.

Illustrative embodiment 18: the non-transitory computer implemented storage medium of claim 17, wherein reconstructing comprises reconstructing the image using a regularized least-square optimization.

Illustrative embodiment 19: the non-transitory computer implemented storage medium of claim 18, wherein the regularized least-square optimization comprises solving:

$$\hat{x} = {min}_{x} {\sum }_{c} {‖ {d}_{c} - {ES}_{c} x ‖}_{2}^{2} + λ R ( x )$$

where x∈ [symbol] , d∈ [symbol] , and E∈ [symbol] is the encoding matrix with E_{n,m}=e^{iφ(r}^{ₘ}^{,t}^{ₙ}⁾, S∈ [symbol] is a diagonal matrix for the coil sensitivity maps, R(.) is a regularizer with λ being a regularization parameter.

Illustrative embodiment 20: the non-transitory computer implemented storage medium of claim 19, wherein:

$$ϕ ( r , t ) = γ {B}_{0} ( r ) t + {\sum }_{l = 1}^{L} {c}_{l} ( t ) {h}_{l} ( r ) ,$$

where B₀(r) is the susceptibility-induced and/or hardware related B₀ field inhomogeneity and γ the gyromagnetic ratio, wherein:

$${c}_{l} ( t ) = γ {\sum }_{T = {t}_{0}}^{t} {B}_{eddy , l} ( T )$$

and wherein:

$${B}_{eddy} ( t ) = - \frac{{dG}_{x} ( t )}{dt} * {f}_{x} ( t ) - \frac{{dG}_{y} ( t )}{dt} * {f}_{y} ( t ) - \frac{{dG}_{z} ( t )}{dt} * {f}_{z} ( t ) ,$$

where Gₓ(t), G_{y}(t), and G_{z}(t) are corresponding waveforms generated by the MR simulator with the MR protocol and ƒₓ(t), ƒ_{y}(t), and ƒ_{z}(t) are system-specific eddy current response functions provided by the spatiotemporal eddy current characteristics and * represents a convolution operation.

1. A method for simulation-based eddy current correction, the method comprising:
determining spatiotemporal eddy current characteristics of an MR scanner;
performing a patient scan using a MR protocol, the patient scan generating MR data;
estimating, by a MR simulator, a dynamic field based on the spatiotemporal eddy current characteristics and the MR protocol;
reconstructing an image from the MR data using at least the estimated dynamic field; and
outputting the image.

2. The method of claim 1, wherein determining the spatiotemporal eddy current characteristics of the MR scanner comprises:
performing a calibration scan by the MR scanner.

3. The method of claim 1, wherein the patient scan is performed with diffusion weighted imaging (DWI).

4. The method of claim 1, wherein estimating the dynamic field comprises a realistic time-dependent magnetic environment experienced during the patient scan.

5. The method of claim 1, wherein reconstructing comprises reconstructing the image using a regularized least-square optimization.

6. The method of claim 5, wherein the regularized least-square optimization comprises solving:
$$\hat{x} = {min}_{x} {\sum }_{c} {‖ {d}_{c} - {ES}_{c} x ‖}_{2}^{2} + λ R ( x ) ,$$
where x∈ [symbol] , d∈ [symbol] , and E∈ [symbol] is an encoding matrix with E_{n,m}=e^{iφ(r}^{ₘ}^{,t}^{ₙ}⁾, S∈ [symbol] is a diagonal matrix for coil sensitivity maps, R(.) is a regularizer with λ being a regularization parameter.

7. The method of claim 6, wherein:
$$ϕ ( r , t ) = γ {B}_{0} ( r ) t + {\sum }_{l = 1}^{L} {c}_{l} ( t ) {h}_{l} ( r ) ,$$
where B₀(r) is a susceptibility-induced and/or hardware related B₀ field inhomogeneity and γ a gyromagnetic ratio, wherein:
$${c}_{l} ( t ) = γ {\sum }_{T = {t}_{0}}^{t} {B}_{eddy , l} ( T ) .$$
wherein:
$${B}_{eddy} ( t ) = - \frac{{dG}_{x} ( t )}{dt} * {f}_{x} ( t ) - \frac{{dG}_{y} ( t )}{dt} * {f}_{y} ( t ) - \frac{{dG}_{z} ( t )}{dt} * {f}_{z} ( t ) ,$$
where Gₓ(t), G_{y}(t), and G_{z}(t) are corresponding gradient waveforms generated by the MR simulator with the MR protocol and ƒₓ(t), ƒ_{y}(t), and ƒ_{z}(t) are system-specific eddy current response functions provided by the spatiotemporal eddy current characteristics and * represents a convolution operation.

8. The method of claim 6, wherein the regularizer is a Tikhonov regularizer, wherein
$$R ( x ) = {‖ x ‖}_{2}^{2} .$$

9. The method of claim 6, wherein the regularizer is a learned regularizer that is enforced effectively through an unrolled iterative algorithm or a diffusion plug-and-play based method, wherein a linear reconstruction algorithm is used to solve the least-square optimization.

10. A system for simulation-based eddy current correction, the system comprising:
an magnetic resonance (MR) scanner configured to acquire MR data of a patient with a patient scan using a MR protocol, the MR scanner further configured to perform a calibration scan to determine spatiotemporal eddy current characteristics of the MR scanner;
a MR simulator configured to estimate a dynamic field based on the spatiotemporal eddy current characteristics and the MR protocol; and
an evaluation unit configured to reconstruct an MR image from the MR data using at least the dynamic field.

11. The system of claim 10, wherein the dynamic field comprises an estimated of a realistic time-dependent magnetic environment experienced during the patient scan.

12. The system of claim 10, wherein the evaluation unit is configured to reconstruct the MR image using a regularized least-square optimization.

13. The system of claim 12, wherein the regularized least-square optimization comprises solving:
$$\hat{x} = {min}_{x} {\sum }_{c} {‖ {d}_{c} - {ES}_{c} x ‖}_{2}^{2} + λ R ( x )$$
where x∈ [symbol] , d∈ [symbol] , and E∈ [symbol] is an encoding matrix with E_{n,m}=e^{iφ(r}^{ₘ}^{,t}^{ₙ}⁾, S∈ [symbol] is a diagonal matrix for coil sensitivity maps, R(.) is a regularizer with λ being a regularization parameter.

14. The system of claim 13, wherein:
$$ϕ ( r , t ) = γ {B}_{0} ( r ) t + {\sum }_{l = 1}^{L} {c}_{l} ( t ) {h}_{l} ( r )$$
where B₀(r) is a susceptibility-induced and/or hardware related B₀ field inhomogeneity and γ a gyromagnetic ratio, wherein:
$${c}_{l} ( t ) = γ {\sum }_{T = {t}_{0}}^{t} {B}_{eddy , l} ( T )$$
and wherein:
$${B}_{eddy} ( t ) = - \frac{{dG}_{x} ( t )}{dt} * {f}_{x} ( t ) - \frac{{dG}_{y} ( t )}{dt} * {f}_{y} ( t ) - \frac{{dG}_{z} ( t )}{dt} * {f}_{z} ( t )$$
where Gₓ(t), G_{y}(t), and G_{z}(t) are corresponding gradient waveforms generated by the MR simulator with the MR protocol and ƒₓ(t), ƒ_{y}(t), and ƒ_{z}(t) are system-specific eddy current response functions provided by the spatiotemporal eddy current characteristics and * represents a convolution operation.

15. The system of claim 13 wherein the regularizer is a Tikhonov regularizer, wherein
$$R ( x ) = {‖ x ‖}_{2}^{2} .$$

16. The system of claim 15, wherein a linear reconstruction algorithm is used to solve the least-square optimization.

17. A non-transitory computer implemented storage medium, including machine-readable instructions stored therein for simulation-based eddy current correction, the instructions when executed by at least one processor, cause the processor to:
determine spatiotemporal eddy current characteristics of an MR scanner;
acquire MR data generated by a MR scan of a patient using a MR protocol;
estimate, using a MR simulator, a dynamic field based on the spatiotemporal eddy current characteristics and the MR protocol;
reconstruct an image from the MR data using at least the estimated dynamic field; and
output the image.

18. The non-transitory computer implemented storage medium of claim 17, wherein reconstructing comprises reconstructing the image using a regularized least-square optimization.

19. The non-transitory computer implemented storage medium of claim 18, wherein the regularized least-square optimization comprises solving:
$$\hat{x} = {min}_{x} {\sum }_{c} {‖ {d}_{c} - {ES}_{c} x ‖}_{2}^{2} + λ R ( x )$$
where x∈ [symbol] , d∈ [symbol] and E∈ [symbol] is an encoding matrix with E_{n,m}=e^{iφ(r}^{ₘ}^{,t}^{ₙ}⁾, S∈ [symbol] is a diagonal matrix for coil sensitivity maps, R(.) is a regularizer with λ being a regularization parameter.

20. The non-transitory computer implemented storage medium of claim 19, wherein:
$$ϕ ( r , t ) = γ {B}_{0} ( r ) t + {\sum }_{l = 1}^{L} {c}_{l} ( t ) {h}_{l} ( r ) ,$$
where B₀(r) is a susceptibility-induced and/or hardware related B₀ field inhomogeneity and γ a gyromagnetic ratio, wherein:
$${c}_{l} ( t ) = γ {\sum }_{T = {t}_{0}}^{t} {B}_{eddy , l} ( T )$$
and wherein:
$${B}_{eddy} ( t ) = - \frac{{dG}_{x} ( t )}{dt} * {f}_{x} ( t ) - \frac{{dG}_{y} ( t )}{dt} * {f}_{y} ( t ) - \frac{{dG}_{z} ( t )}{dt} * {f}_{z} ( t ) ,$$
where Gₓ(t), G_{y}(t), and G_{z}(t) are corresponding gradient waveforms generated by the MR simulator with the MR protocol and ƒₓ(t), ƒ_{y}(t), and ƒ_{z}(t) are system-specific eddy current response functions provided by the spatiotemporal eddy current characteristics and * represents a convolution operation.
